(19) United States
(12) Patent Application Publication
(10) Pub. No.: US 2002/0121893 A1
(43) Pub. Date: Sep. 5, 2002

(54) Device for low-power current detection

(76) Inventor: Alain Chapuis, Riedikon (CH)

Correspondence Address: David M. Carter, Carter & Schnedler, P.A., 56 Central Avenue, Suite 101, P.O. Box 2985, Asheville, NC, 28802, US

(21) Appl. No.: 10/083,221

(22) Filed: Feb. 26, 2002

(30) Foreign Application Priority Data
Mar. 1, 2001 (DE) 101 09 833.2

(51) Int. Cl. G01R 1/00

(52) U.S. Cl. 324/126

(57) ABSTRACT

The invention concerns a device for low-power current detection by means of a shunt resistor (Rₛₕᵤₙₜ) generating a shunt voltage, with an amplifier network, implemented to amplify the shunt voltage into a measurement voltage, having a first nullator-norator combination (N₁, /N₁) wired as an amplifier, with a second nullator-norator combination (B₂) being connected in series upstream from the first nullator-norator combination in the direction of the shunt resistor in such a way that the first nullator and the second nullator are operated in a feedback loop and non-linearity of the first nullator is corrected by an opposing behavior of the second nullator, with a feedback signal for the second nullator-norator combination being picked up at the output of the first nullator-norator combination.

### BACKGROUND OF THE INVENTION

The present invention concerns a device for low-power current detection by means of a shunt resistor which generates a shunt voltage.

This type of current measurement for generating a measurement voltage Uₘₑₛₛ via a shunt resistor Rₛₕᵤₙₜ, as shown schematically in FIG. 4, is known from the prior art as the principal method for current measurement.

In power electronics in particular, such as in voltage transformers, typical integrated circuits for driving corresponding power semiconductors have an input for regulating a current, which is usually inductive, with the required voltage level being comparatively high, in the range of approximately 1 volt, in order to ensure a favorable noise-voltage interval. Current detection in this case requires relatively large resistance values (depending on the power) for a shunt resistor, with associated relatively high losses and negative effects on the efficiency.

A possible method for reduction of the power loss known from the prior art is by means of a current transformer, such as a transformer. However, a transformer is not suitable for long-term current detection due to its magnetic properties (and/or the necessity for this type of current transformer to periodically demagnetize itself).

Accordingly, it can therefore suggest itself that a small shunt resistor be selected (to reduce the power loss) and the correspondingly small measurement signal Uₘₑₛₛ be amplified through a suitable amplifier, in order to then be able to perform suitable current detection by means of a circuit module connected downstream.

Typical semiconductor-based amplifier topologies, however, have the disadvantage that they are costly to produce, particularly when they are realized as multistage, often have a non-linear amplification characteristic over the amplification range, and, in addition, can only be operated in a limited frequency range, i.e., their usable frequency bandwidth is limited.

Particularly the problem of non-linearity of this type of transistor amplifier, which is usually single stage, is to be described with reference to the basic circuit diagram of FIG. 5, with an amplifier transistor, connected downstream from the shunt resistor Rₛₕᵤₙₜ, to be described with the aid of the two-pole “nullator” N₁ and “norator”/N₁ known from network theory, as wired in FIG. 5 with resistors R₁, R₂. To be precise, a transistor can be described as a nullator-norator basic circuit diagram of a type such that the base emitter junction is described by the nullator and the collector emitter junction is described by the norator; nullator and norator are correspondingly connected to the emitter, so that in the idealized case both the base emitter voltage and the base current are equal to zero, and the collector emitter voltage and the collector current are dependent on the external circuit elements. In the amplifier equivalent circuit diagram of FIG. 5, the resistor R₁ thereby corresponds to the emitter resistance and R₂ to the collector resistance, with the amplification factor −x for the measurement voltage Uₘₑₛₛ being formed as the quotient of R₂ and R₁. In the equivalent circuit diagram from the prior art shown in principle in FIG. 5, the amplification is thereby negative (i.e., with the polarity reversed), so that typically a further transistor stage (in principle, the same nullator-norator combination), with an assumed amplification −y, is connected downstream from the arrangement according to FIG. 5 and the overall amplification x·y is therefore positive.

The arrangement of FIG. 5 is, as noted, an otherwise known single-stage transistor amplifier, with the form of the description used, having the idealized network elements norator and nullator known from network theory, also indicating a problem in principle, namely an actual non-linearity of the nullator N₂ when it is realized with concrete components, e.g., a transistor, with a corresponding disadvantageous effect on the precision of the measurement arrangement over the total range. This actual non-linearity is the result of influence (modulation) of the nullator by the associated norator/N₁ and leads to the non-linear amplification characteristic of the system and thereby to its poor suitability for highly precise current detection.

### OBJECTS OF THE INVENTION

One object of the present invention is therefore, in measurement arrangements of this type for low-power current detection, to improve the linearity of a downstream amplifier network by means of a shunt resistor, with the power loss via the shunt resistor (and therefore the worsening of efficiency caused by the current measurement) to remain minimized.

### SUMMARY OF THE INVENTION

The present invention is particularly suitable for use with voltage transformers in power electronics, and further preferred in this case for DC-DC transformers.

It is thus advantageously provided according to one form of the invention that a second nullator-norator combination be connected upstream from the first nullator-norator combination, each preferably realized as a transistor and/or transistor pair, in such a way that correction of a non-linear amplification behavior of the first nullator-norator combination can occur through the second nullator-norator combination.

This is achieved through feedback, with the feedback signal for the second nullator-norator combination generated at the output of the first combination.

In a way which is particularly significant in practice, the respective nullator-norator combinations are implemented as transistors and/or transistor pairs, with the current through the second nullator-norator combination (as a transistor) adjusted with the aid of a further nullator (of the same transistor pair) in such a way that the desired linearizing effect arises from the first nullator (of the first combination) and the second nullator (from the second combination) in the series circuit.

The degree of feedback (it is preferred that oscillation and/or rising of the arrangement are suppressed) is thereby adjusted by the respective emitter resistances. While on one hand resistor components and/or discrete resistors could be used for this purpose, it also suggests itself in the framework of the present invention that these types of resistance values be set up through appropriate dimensioning of the semiconductor used; this usage is particularly suitable for a realization of the amplifier topology according to the present invention as an integrated circuit.

As a result, an extremely low-power (loss) current detection can be realized because, to generate a shunt voltage in the millivolt range, a shunt resistor in the range of mere milliohms is necessary. The principle of the present invention simultaneously makes it possible to realize a very high maximum operating frequency, so that current detection according to the invention is not only highly linear over the amplifying range, but also has a large usable bandwidth of operating frequency.

### BRIEF DESCRIPTION OF THE DRAWINGS

Further advantages, features, and characteristics of the invention arise from the following description of preferred exemplary embodiments and with reference to the drawings:

FIG. 1 shows a first schematic circuit diagram of a device according to the invention for low-power current detection according to a first preferred embodiment of the invention;

FIG. 2 shows a concrete realization in circuit technology of the embodiment according to FIG. 1;

FIG. 3 shows a second, alternative embodiment of the present invention;

FIG. 4 shows a general principle for current measurement by means of a shunt resistor from the prior art; and

FIG. 5 shows a basic circuit diagram of current measurement by means of a shunt resistor and a single-stage transistor amplifier connected downstream, which is depicted as a nullator-norator combination.

### DESCRIPTION OF THE PREFERRED EMBODIMENTS

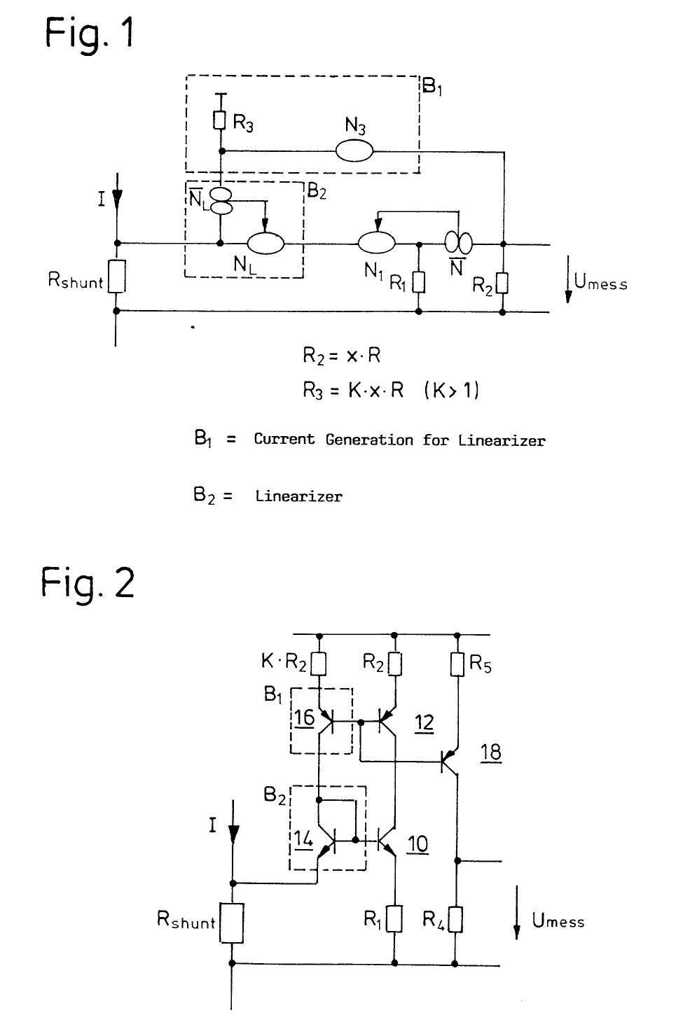

With reference to FIG. 1, it is clear that a first combination of nullator N₁ and norator/N₁ with associated resistors R₁ and/or R₂, corresponding to the transistor amplifier from the prior art according to FIG. 5, has a second nullator-norator combination (dashed line B₂) connected upstream in the direction of the shunt resistor Rₛₕᵤₙₜ. To be precise, a second nullator N_{L} of the second nullator-norator combination B₂ is connected in series with the first nullator N₁, while the associated second norator/N_{L} is connected with ground via a resistor R₃. In FIG. 1, each of the arrows pointing from the norator to the nullator symbolizes the effects (modulation), corresponding to an actual non-linear behavior of the norator concerned, on the associated nullator.

In addition, a further nullator N₃ is shown in FIG. 1, symbolized with the dashed line B₁, which feeds back the output of the first norator/N₁ (and therefore the output for the measurement voltage Uₘₑₛₛ) to the input of the second norator/N_{L}, with the operating current for the second (correcting) nullator-norator combination B₂ being adjusted in such a way, by means of resistor R₃, that it corresponds to the operating current of the first nullator/norator combination and the coupling factor is determined by the resistance value R₃.

To be precise, the amplification of the arrangement symbolically shown in FIG. 1 is determined in turn by the factor x as a quotient of R₂ and R₁, and an amplification factor and/or coupling factor k of the second nullator-norator combination B₂ is also analogously determined as a quotient of R₃ and R₂, so that the following must apply:

R₃=k·R₂=k·x·R₁

(with k>1 advantageously applying, so that the arrangement runs robustly and cannot oscillate).

FIG. 2 illustrates a concrete conversion in circuit technology of the symbolic network circuit diagram according to FIG. 1, with the first nullator-norator combination N₁, /N₁ being realized by an npn/pnp transistor pair 10, 12, the second nullator-norator combination B₂ being realized by an npn transistor 14, and the third nullator N₃ being realized as a further pnp transistor 16. Correspondingly, the adjustment of the feedback occurs through suitable dimensioning of the factor k for the emitter resistance R₃=k·R₂ for the transistor 16, relative to the emitter resistance R₂ for the transistor 12, and the amplification factor for the circuit arrangement at the collector output of the transistors 12 and/or 14 is correspondingly determined for the transistor 10 by the quotients of emitter resistance R₂ and emitter resistance R₁.

As can additionally be seen from FIG. 2, a further amplifier stage is connected downstream from the arrangement of the transistors 10 to 16 (which, in the circuit shown, implement a double current mirror) by means of the transistor 18, at which the actual measurement voltage Uₘₑₛₛ is then picked up on the collector side, with this further transistor 18 being wired by resistors R₄ and/or R₅ in a way which is otherwise known. As already described above, the additional amplifier stage with transistor 18 merely serves, however, for the purpose of again reversing a negative polarity of the amplified voltage signal at the collector of the transistors 10 and/or 12.

In operation, feedback is achieved by the transistor 16 wired as the operating current generator for the transistor 14 with the resistance k·R₂, which, through a characteristic which is switched opposite, corrects a non-linearity of the transistor 10 with its own non-linear amplification, so that as a result, an amplifier arrangement arises which has extensively linear amplification characteristics over a wide amplification range and is thus suitable for exact current measurement. This arrangement is simultaneously distinguished by a comparatively simple circuit design (and is therefore also particularly suitable for integration in an integrated circuit) and has a high maximum operating frequency, which makes it also particularly suitable for use in connection with voltage transformers in power electronics.

In practical realization, an arrangement thus results which realizes an amplification factor of a magnitude of 10 for a typical shunt resistor of approximately 1 to 500 milliohms, preferably 10 to 200 milliohms and a shunt voltage in the millivolt range, typically 10 to 50 millivolts. The amplification circuit is usable up to the three-digit MHz range.

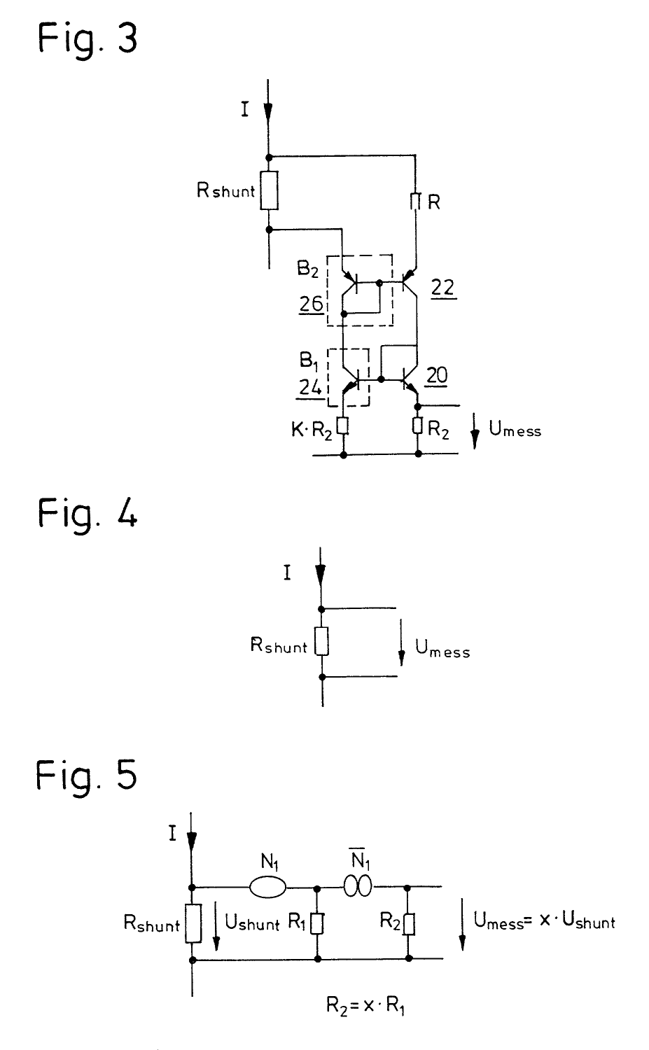

FIG. 3 shows an alternative realization of the exemplary embodiment according to FIG. 2 of a design, such that transistors 20 to 26 realize a corresponding (doubled) current mirror circuit, however, with reversed polarity of each of the transistors used, so that an amplifier stage (by means of transistor 18 in FIG. 2) for polarity reversal connected downstream can be dispensed with.

The present invention is not restricted to the exemplary embodiments shown. Thus, it particularly suggests itself that the exemplary embodiments shown, instead of being realized with discrete transistor components, could also be realized through appropriate integrated circuit environments, with it being particularly preferred here that the respective assigned resistances be converted through suitable dimensioning of the semiconductor elements themselves and/or the corresponding doped surfaces and paths. Alternatively, it is possible, and also included in the present invention, that the network two-pole norator and nullator, used for the description in principle of the present invention, be implemented by other semiconductor components, such as operational amplifiers or similar devices, in the way shown.

From the foregoing description of the preferred embodiments of the invention, it will be apparent that many modifications may be made therein. It should be understood, however, that these embodiments of the invention are an exemplification of the invention only and that the invention is not limited thereto. It is to be understood, therefore, that it is intended in the appended claims to cover all modifications as fall within the true spirit and scope of the invention.

1. A device for low-power current detection by a shunt resistor (Rₛₕᵤₙₜ) generating a shunt voltage, having
an amplifier network implemented for amplification of the shunt voltage into a measurement voltage, which has a first nullator-norator combination (N₁, /N₁) wired as an amplifier,
characterized in that
a second nullator-norator combination (B₂) is connected in series upstream from the first nullator-norator combination in the direction of the shunt resistor in such a way that the first nullator and the second nullator are operated in a feedback loop, and non-linearity of the first nullator can be corrected by an opposing behavior of the second nullator,
with a feedback signal for the second nullator-norator combination being picked up at the output of the first nullator-norator combination.

2. A device according to claim 1, characterized in that the first nullator-norator combination is realized as an npn/pnp transistor pair connected at the collector side (10, 12; 20, 22) and the second nullator-norator combination is a transistor (14; 24) of a second npn/pnp transistor pair (14, 16; 24, 26) whose operating current is adjusted in such a way that it corrects for non-linearity of the transistor of the first transistor pair acting as a nullator.

3. A device according to claim 2, characterized in that operating current generation (B₁) for the second nullator-norator combination is realized through a second transistor (16; 26) of the second npn/pnp transistor pair.

4. A device according to claim 2, characterized in that amplification of the amplifier network is adjusted by resistors (R₁, R₂, k·R₂) provided on the emitter side at the transistor pairs.

5. A device according to claim 2, characterized in that a degree of the feedback (k) is set through a resistance ratio of an emitter resistance (R₃) of the second nullator-norator combination relative to a corresponding emitter resistance (R₂) of the first nullator-norator combination.

6. A device according to claim 2, characterized in that a degree of the feedback (k) is set by dimensioning of the semiconductor geometries of the semiconductors which realize the first and/or the second nullator-norator combination.

7. A device according to claim 1, characterized in an amplification factor of the amplifier network lies between 5 and 20.

8. A device according to claim 1, characterized in the shunt resistor has a value in the range between 1 and 500 milliohms.

9. A device according to claim 1, characterized in a maximum operating frequency of the amplifier network lies he range between 10 and 100 MHz.

10. A device according to claims 1, characterized in the device is used for current detection in a DC-DC transformer.
